(19) United States
(12) Patent Application Publication
(10) Pub. No.: US 2007/0176302 A1
(43) Pub. Date: Aug. 2, 2007

(54) Low temperature co-fired ceramic module and method of manufacturing the same

(75) Inventors: Tae Soo Lee, Seoul (KR); Yun Hwi Park, Yongin (KR); Taek Jung Lee, Hwasung (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/643,693

(22) Filed: Dec. 22, 2006

(30) Foreign Application Priority Data
Feb. 1, 2006 (KR) 10-2006-0009829

(51) Int. Cl. H01L 23/48; H01L 21/00

(52) U.S. Cl. 257/782; 257/783; 438/118; 257/E23.04

(57) ABSTRACT

An LTCC module includes an LTCC substrate and a pad part formed on an undersurface of the LTCC substrate for mounting the LTCC substrate to an external substrate. The pad part includes a metal pad layer formed on an undersurface of the LTCC substrate and a solder layer formed on an undersurface of the metal pad layer.

### CLAIM OF PRIORITY

This application claims the benefit of Korean Patent Application No. 2006-0009829 filed on Feb. 1, 2006, in the Korean Intellectual Property Office.

### BACKGROUND OF THE INVENTION

1. Field of the Invention

The present invention relates to a Low Temperature Co-fired Ceramic (LTCC) module and, more particularly, to an LTCC module having a pad part exhibiting excellent adhesive strength and reliability when mounted to an external substrate, and to a manufacturing method thereof.

2. Description of the Related Art

Currently, mobile communication devices such as personal portable terminals are miniaturized, light-weight and adopting RF applications. In response, circuit modules used in the communication devices are also required to be miniaturized, light-weight and highly functional. In particular, Low Temperature Co-fired Ceramic (LTCC) modules adopting LTCC substrates have been proposed recently. Using the LTCC substrates, circuit wires can be configured in the form of through holes or vias, which facilitate forming current paths leading to external terminals or terminals for surface mounting devices (SMD). In addition, the LTCC modules adopt a Land Grid Array (LGA)-type packaging method to accommodate a plurality of input/output electrodes on an undersurface thereof.

An LGA-type LTCC module includes pad parts arranged in an array on an undersurface of the substrate. Each of the pad parts is composed of a Cu-based metal pad layer formed on an undersurface of the LTCC substrate. The metal pad layer is metal-finished via Au or Ni/Au plating, etc.

FIG. 1(a) is a bottom view and FIG. 1(b) is a sectional view, both illustrating a conventional LTCC module. In particular, FIG. 1 illustrates a state (an array of unit modules) of the LTCC module before diced into individual unit modules. Referring to FIGS. 1(a) and (b), the LTCC module 10 includes an LTCC substrate 11 and a metal pad layer 20 formed on an undersurface of the LTCC substrate 11. On the LTCC substrate 11, a surface mounting part 17 including an integrated circuit chip or other devices is formed. The surface mounting part 17 may for example be encapsulated by an appropriate resin encapsulant.

The metal pad layer 20 constitutes an electrode pad part for connecting the LTCC module 10 with an external substrate. As shown, the metal pad layer 20 is composed of a Cu or Ag-based first metal layer 13 and an Au-plated layer 15 formed on an undersurface of the first metal layer 13. A Ni/Au-plated layer (Au layer underneath Ni layer) can be adopted instead of the Au-plate layer 15. As described above, the metal finish material of the electrode pad part can be an Au-plated layer or an Ni/Au-plated layer. After the electrode pad part is formed, the LTCC module 10 is diced into individual modules and mounted on an external substrate (not shown) such as a mother-board. When mounting the LTCC module, heated solder is applied on a corresponding portion of the external substrate, and the metal pad layer 20 of the LTCC module 10 is attached to the external substrate by this solder.

However, the metal pad layer 20 of the conventional LTCC module 10 described above does not provide stable adhesive strength when soldered to the external substrate. That is, because of mismatching in thermal characteristics such as thermal expansion coefficients between the ceramic material of the LTCC module and the external substrate (typically made of organic PCB), good soldering is rarely expected. The low adhesive strength between the LTCC module and the external substrate can be confirmed through for example a drop test. Especially when the size of individual LTCC modules is large, the soldering is more unstable.

### SUMMARY OF THE INVENTION

The present invention has been made to solve the foregoing problems of the prior art and therefore an aspect of the present invention is to provide a Low Temperature Co-fired Ceramic (LTCC) module which has excellent adhesive reliability between a pad part thereof and an external substrate.

Another aspect of the invention is to provide a manufacturing method of an LTCC module which can increase the adhesive reliability between a pad part of the LTCC module and an external substrate.

According to an aspect of the invention, the invention provides an LTCC module. The LTCC module includes: an LTCC substrate; and a pad part formed on an undersurface of the LTCC substrate for mounting the LTCC substrate to an external substrate, wherein the pad part includes a metal pad layer formed on an undersurface of the LTCC substrate and a solder layer formed on an undersurface of the metal pad layer.

According to a certain embodiment of the present invention, the pad part is composed of a Land Grid Array (LGA) type electrode pad, and the solder layer may be made of Pb—Sn or Ag—Sn.

According to a certain embodiment of the present invention, the metal pad layer includes: a first metal layer formed on an undersurface of the LTCC substrate; and an Au-plated layer as a second metal layer formed on an undersurface of the first metal layer. The first metal layer may be made of Cu or Ag. The metal pad layer may further include an Ni-plated layer formed between the first metal layer and the Au-plated layer.

The LTCC module may further include a surface mounting part formed on a top surface of the LTCC substrate. In particular, the surface mounting part may include a device encapsulated by a resin encapsulant.

According to another aspect of the invention, the invention provides a method of manufacturing a Low Temperature Co-fired Ceramic (LTCC) module includes: forming a metal pad layer on an undersurface of an LTCC substrate for connection with an external substrate; and forming a solder layer on an undersurface of the metal pad layer.

According to a certain embodiment of the present invention, the step of forming the metal pad layer includes: forming a first metal layer with Cu or Ag on an undersurface of the LTCC substrate; and forming an Au-plated layer on an undersurface of the first metal layer. In addition, the step of forming the metal pad layer may further include forming a Ni-plated layer on an undersurface of the first metal layer between the step of forming the first metal layer and the step of forming the Au-plated layer.

The method may further include forming a surface mounting part on a top surface of the LTCC substrate between the step of forming the metal pad layer and the step of forming the solder layer. The surface mounting part may be prepared by mounting at least one device on a top surface of the LTCC substrate and encapsulating the device with a resin encapsulant.

The method may further include dicing a resultant structure with the solder layer formed thereon into individual modules after the step of forming the solder layer. In addition, the method may further include mounting the diced individual modules on the external substrate such as a mother-board after the step of dicing into individual modules. The step of mounting the individual modules on the external substrate includes: forming a solder on a mounting surface of the external substrate; and heating the solder layer of the LTCC module and the solder of the external substrate to bond the solder layer of the LTCC module and the solder of the external substrate together. It is preferable that the solder layer of the LTCC module and the solder of the external substrate are made of the same material.

According to a certain embodiment of the present invention, the solder layer is formed on an undersurface of the LTCC module as a metal finish material of an electrode pad. That is, the pad part of the LTCC module itself has a solder formed thereon. Using this pad part having the solder layer, the LTCC module soldered to a mounting surface of the external substrate has excellent anti-impact and anti-drop reliability. That is, the solder layer formed on the pad part of the LTCC module and the solder applied on a mounting surface of the external substrate are heated and bonded together, achieving excellent adhesive strength and thereby significantly improving the reliability of a product.

### BRIEF DESCRIPTION OF THE DRAWINGS

The above and other objects, features and other advantages of the present invention will be more clearly understood from the following detailed description taken in conjunction with the accompanying drawings, in which:

FIG. 1(a) is a bottom view and FIG. 1(b) is a sectional view, illustrating a conventional LTCC module;

FIG. 2 is a bottom view illustrating an LTCC module according to an embodiment of the present invention;

FIG. 3 is a sectional view-illustrating the LTCC module according to the embodiment of the present invention;

FIG. 4 is a sectional view illustrating an LTCC module according to another embodiment of the present invention;

FIGS. 5 to 9 are sectional views illustrating a manufacturing method of an LTCC module according to an embodiment of the present invention;

FIGS. 10(a) and (b) are pictures taken on bottom surfaces of LTCC modules according to Comparative Example and Inventive Example, respectively; and

FIG. 11 is a graph illustrating the results of a drop test performed on the LTCC modules according to Comparative Example and Inventive Example, respectively.

### DETAILED DESCRIPTION OF THE PREFERRED EMBODIMENT

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals are used throughout to designate the same or similar components.

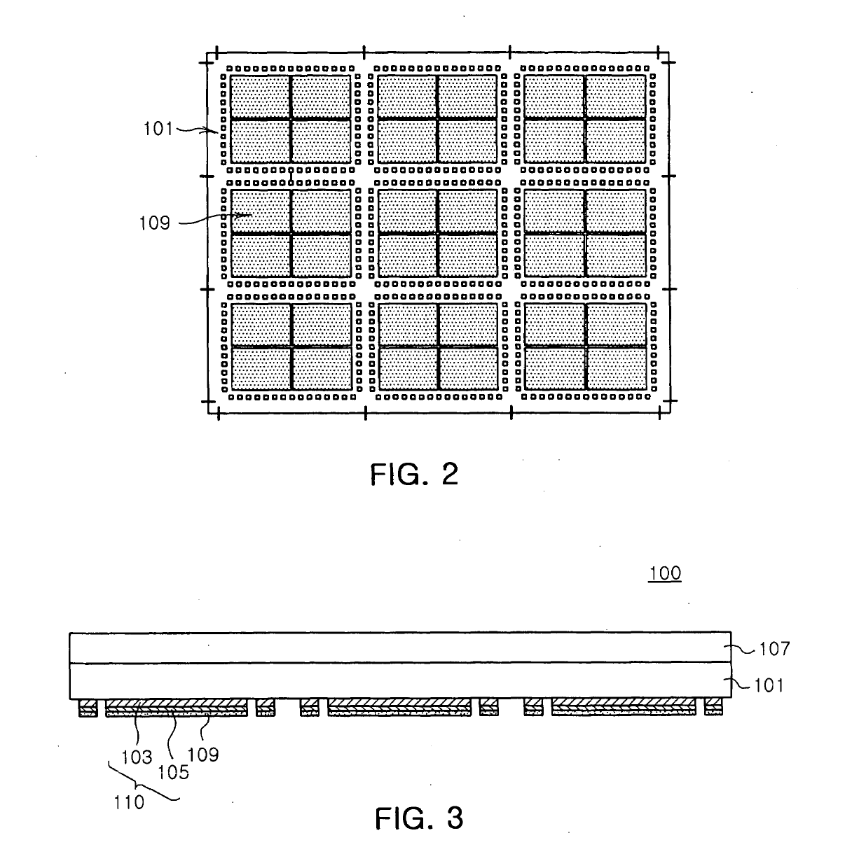

FIGS. 2 and 3 are a bottom view and a sectional view illustrating an LTCC module according to an embodiment of the present invention. In particular, the LTCC module 100 shown in FIGS. 2 and 3 is an aggregate of modules before diced into individual modules.

Referring to FIGS. 2 and 3, the LTCC module 100 includes an LTCC substrate 101 and a pad part 109 and 110 formed on an undersurface of the substrate 101. A surface mounting part 107 is disposed on a top surface of the LTCC substrate 101. The surface mounting part 107 includes at least one device (surface mounting-type active or passive devices including integrated circuit chip, resistor, capacitor, chip inductor, etc.). The device can be encapsulated by a resin encapsulant, protected from external environment or impacts.

The pad part 109 and 110 can function as an electrode terminal for mounting the LTCC module 100 to an external substrate (e.g. a mother-board made of organic PCB). In particular, the pad part 109 and 110 forms an electrode terminal of Land Grid Array (LGA) type (in which electrode terminals are arranged in an array on an undersurface of a substrate). Such an LGA-type pad part is suitable for accommodating a plurality of electrode terminals in a small area and exhibits smaller inductance.

The pad part 109 and 110 includes a metal pad layer 110 formed on an undersurface of the LTCC substrate 101 and a solder layer 109 formed on an undersurface of the metal pad layer 110. The metal pad layer 110 includes an Ag-based first metal layer 103 and an Au layer 105 as a second metal layer formed on an undersurface of the first metal layer 103. Conventionally, the Au layer 105 is made to directly contact solder applied on a mounting surface of the external substrate without a solder layer 109, but in the present invention, a solder layer 109 is formed on an undersurface of the Au-plated layer 105 as an additional metal finish material. This Au layer 105 can be formed on an undersurface of the first metal layer 103 via a plating process such as electroless plating, after the first metal layer 103 is formed.

The solder layer 109 can be for example made of Pb—Sn or Ag—Sn. The solder layer 109 is one component of the pad part of the LTCC substrate 101. Later when individual LTCC modules are mounted on the external substrate, the solder layer 109 is heated, and the heated solder layer 109 is fusion-bonded or adhered to a solder (preferably, made of the same material as the solder layer 109) provided on a mounting surface of the external substrate. Thereby, stable adhesive reliability or adhesive strength is obtained between the LTCC module and the external substrate.

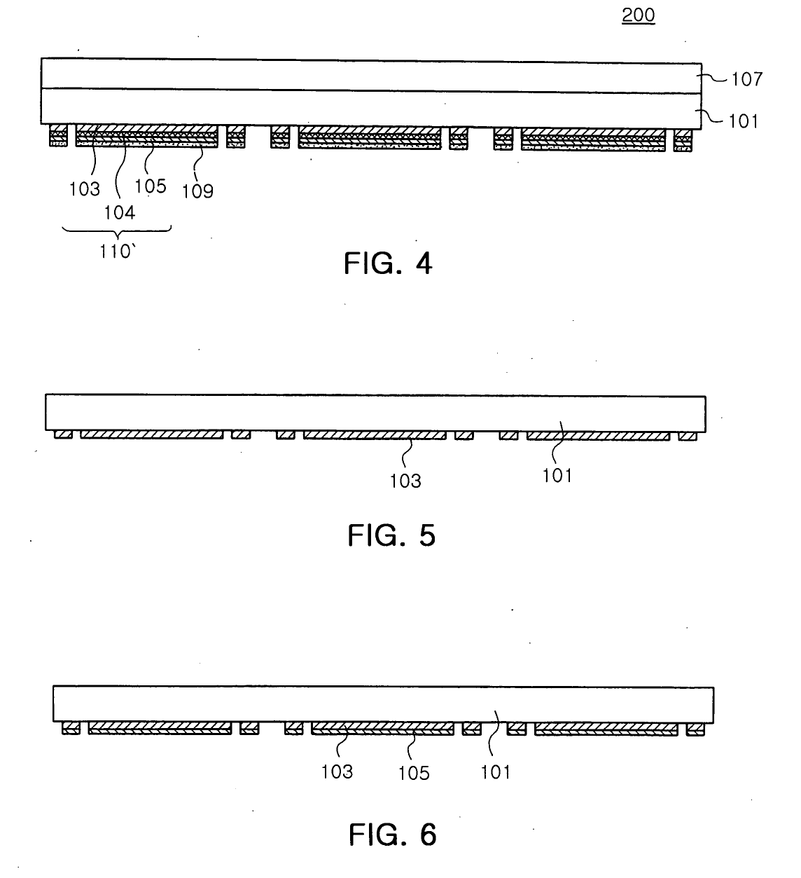

FIG. 4 is a sectional view illustrating an LTCC module according to another embodiment of the present invention. Referring to FIG. 4, this embodiment is identical to the one shown in FIG. 3, except that an Ni-plated layer 104 is additionally formed between the metal pad layer 110′ and the Au-plated layer 105. Such an Ni/Au-plated layer 104 and 105 is a second metal layer formed on an undersurface of the first metal layer 103, more effective for protecting the first metal layer 103. As shown, similar to the afore described embodiment, the pad part of the LTCC module 200 includes a solder layer 109 as a component formed on a lowermost part thereof in this embodiment.

Now, a manufacturing method of an LTCC module will be explained hereunder (including the step of mounting to an external substrate).

FIGS. 5 to 10 are sectional views illustrating the manufacturing method of the LTCC module according to an embodiment of the present invention. First, referring to FIG. 5, a first metal layer 103 for an electrode pad is formed on an undersurface of the LTCC substrate 101. The first metal layer 103 may be formed for example by applying metal paste containing Ag or Cu on an undersurface of a ceramic substrate (i.e., a substrate before being co-fired) and co-firing the ceramic substrate subsequently.

Next, as shown in FIG. 6, Au electroless plating is performed on an undersurface of the first metal layer 103. Thereby, an Au-plated layer 105 is formed as a second metal layer on an undersurface of the first metal layer 103. Alternatively, Ni/Au electroless plating can be performed instead of the Au electroless plating, and in this way, an Ni/Au-plated layer is sequentially formed as a second metal layer on an undersurface of the first metal layer 103 (see FIG. 4).

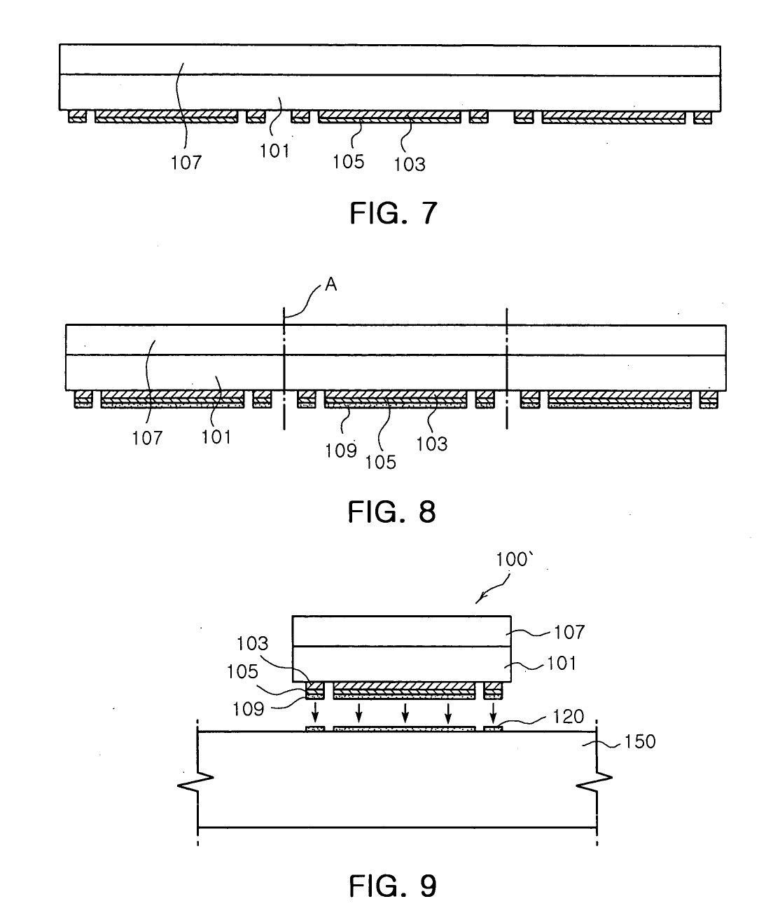

Then, as shown in FIG. 7, a packaging process is conducted to mount necessary electronic devices on a top surface of the LTCC substrate 101. Through this packaging process, a surface mounting part 107 is disposed on a top surface of the LTCC substrate 101. In this packaging process, at least one device (integrated circuit chip, resistor, chip inductor, etc) is mounted on a top surface of the LTCC substrate 101, and the device can be encapsulated by a resin encapsulant. Although not shown, vias may be formed in the LTCC substrate 101 for connecting terminal electrodes with the device, and the necessary electronic device may also be embedded in the substrate 101.

Next, as shown in FIG. 8, a solder layer 109 is formed on an undersurface of the Au-plated layer 105. The solder layer 109 can be formed with lead solder material such as Pb—Sn or lead-free solder material such as Ag—Sn. The solder layer 109 is one component of the pad part of the LTCC module, and can be heated later when mounting the LTCC module to an external substrate. Thereafter, the LTCC module in the form of an array of individual modules is cut, i.e., diced into the individual modules. The line A in FIG. 9 denotes a dicing line. Thereby, individual unit LTCC modules are obtained. Each of the pad parts of the individual LTCC modules forms an LGA-type electrode pad with a plurality of electrode terminals arranged in an array.

Next, each of the individual LTCC modules 100′ is attached and mounted on an external substrate 150 such as a mother-board (see FIG. 9). For example, a solder 120, made of the same material as the solder layer 109 formed on an undersurface of the LTCC module, can be applied on a mounting surface of the external substrate 150. Then the solder 120 for the external substrate and the solder layer 109 of the LTCC module are placed in contact with each other and heated. Thereby, the individual LTCC module 100′ is stably and firmly adhered to a mounting surface of the external substrate 150. That is, the solder layer 109 formed on an undersurface of the individual LTCC module 100′ and the solder 120 applied on a mounting surface of the external substrate 150 have similar (or identical) thermal characteristics, thereby significantly enhancing the adhesive strength and reliability between the individual LTCC module 100′ and the external substrate 150.

### EXAMPLE

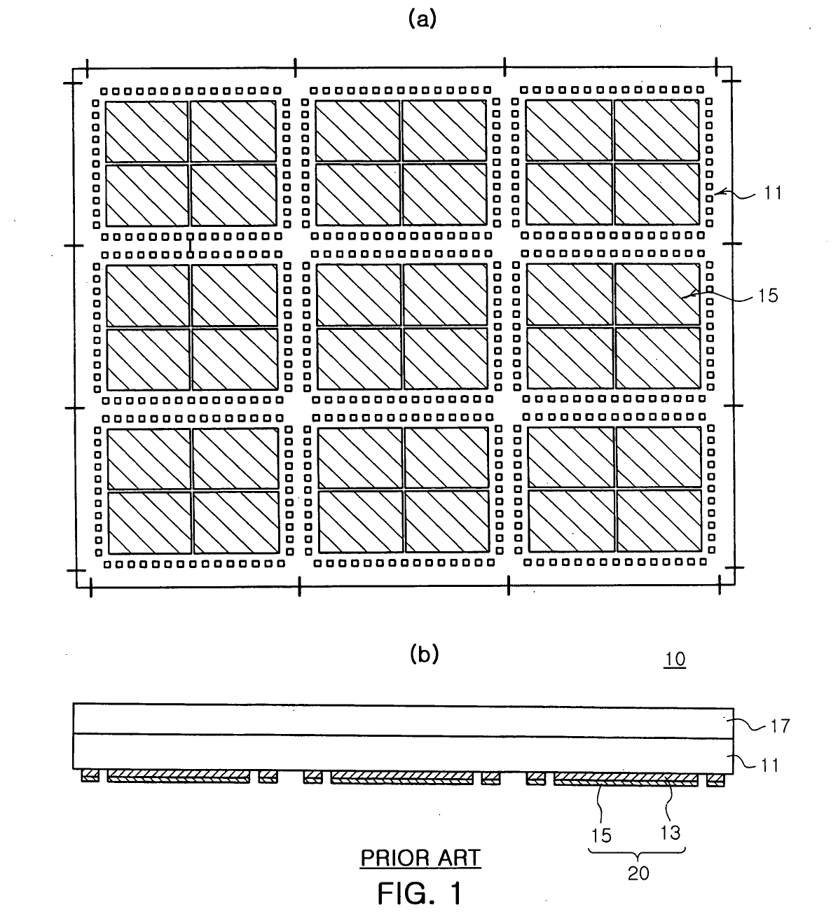

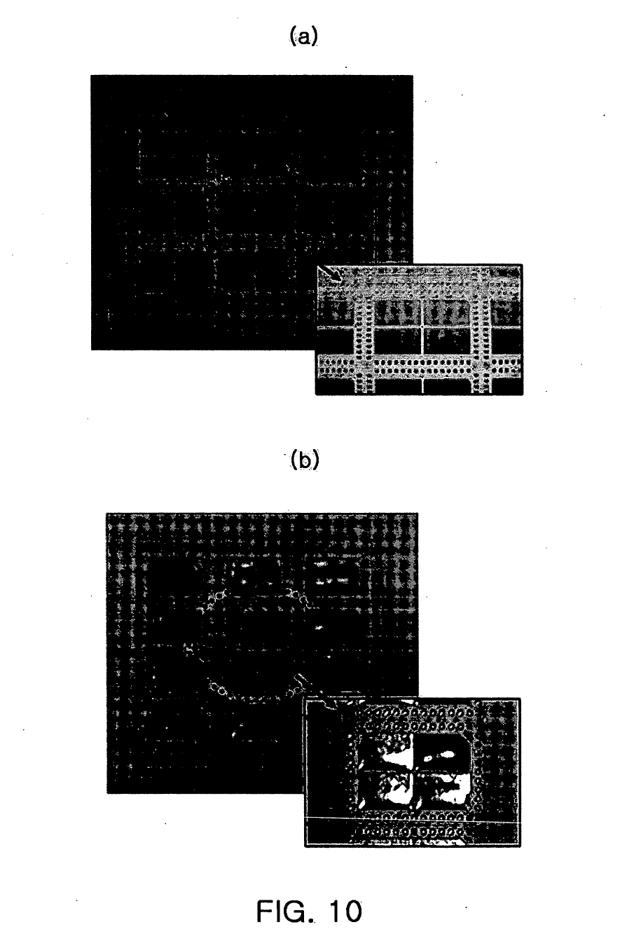

To confirm the significantly enhanced adhesive reliability by the method of manufacturing the LTCC module according to the present invention compared with the conventional method, the inventors have conducted a drop reliability test (also simply referred to as a drop test). The LTCC module samples used in this reliability test are shown in FIG. 10. FIG. 10(a) shows a sample by Comparative Example, in which an electrode pad includes a Cu metal layer and a Ni/Au-plated layer sequentially formed, as in the conventional method (see FIG. 1(b)). FIG. 10(b) illustrates a sample by Inventive Example, in which the electrode pad includes a Cu metal layer, a Ni/Au-plated layer and a solder layer sequentially formed (see FIG. 3). That is, the electrode pad of the Comparative Example uses a Ni/Au-plated layer as a metal finish material, but the electrode pad of the Inventive Example uses a solder layer as the metal finish material. These samples of the Comparative and Inventive samples having different metal finish materials were adhered and mounted to organic PCBs, respectively and tested by a drop test.

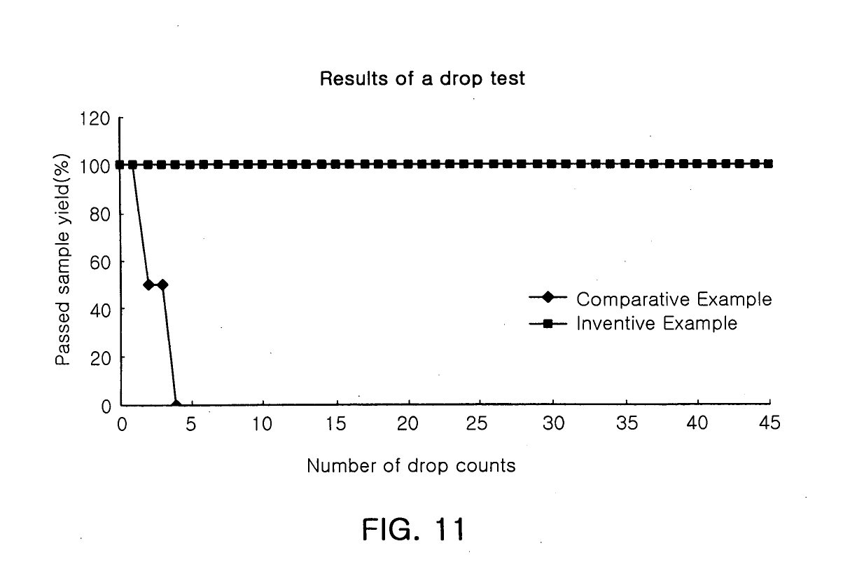

All samples were LGA-type LTCC modules with a dimension of 5 mm×5 mm. The Ni/Au-plated layer of the Comparative and Inventive Examples was formed by electroless plating. The solder layer formed on the sample of the Inventive Example is made of Pb—Sn as a main substance. The drop test was conducted by a total of 45 times of drops. The results from this drop test are shown in the following Table 1 and the graph in FIG. 11. In the graph of FIG. 11, the x-axis represents the number of drop counts and the y-axis represents the passed (not destructed) sample yield. In addition, the fracture count refers to the number of drops performed until the module is destructed.

TABLE 1

| | | | Metal finish | | |
|---|---|---|---|---|---|
| | Sample | Electrode | material of | Fracture | Pass/ |
| Sample | size | pad type | electrode pad | count | Fail |
| Comparative | 5 mm × | LGA | Electroless Ni/Au | Up to 5 | Fail |
| | 5 mm | | | | |
| Inventive | 5 mm × | LGA | Solder layer | Exceeding | Pass |
| | 5 mm | | | 45 | |

As shown in Table 1 and FIG. 11, the sample according to the Inventive Example exhibited excellent adhesive reliability, whereas the sample according to the Comparative Example exhibited low adhesive reliability. That is, most of the samples of the Comparative Example were destructed after 5 drops. However, the samples of the Inventive Example were not destructed at all with 100% of passing yield up to 45 drops (That is, the modules were not detached from the external substrates).

As described above, the solder layer is formed on the Ni/Au-plated layer as a metal finish material in advance, thereby achieving significantly improved adhesive reliability. Therefore, due to the excellent adhesive strength of the pad part, the present invention can be applied to the LTCC modules having a dimension of 10 mm×10 mm or larger to obtain high soldering reliability.

According to the present invention set forth above, a solder layer is formed on an electrode pad part in advance, significantly improving soldering characteristics between an LTCC module and an external substrate, more particularly, an LTCC module and an organic PCB. This enhances the adhesive strength between the LTCC module and the external substrate and allows excellent anti-drop or anti-impact reliability. Furthermore, the invention is easily applied to an LTCC module having a dimension of at least 10 mm×10 mm to obtain excellent soldering reliability.

While the present invention has been shown and described in connection with the preferred embodiments, it will be apparent to those skilled in the art that modifications and variations can be made without departing from the spirit and scope of the invention as defined by the appended claims.

What is claimed is:

1. A Low Temperature Co-fired Ceramic (LTCC) module comprising:
an LTCC substrate; and
a pad part formed on an undersurface of the LTCC substrate for mounting the LTCC substrate to an external substrate,
wherein the pad part comprises a metal pad layer formed on an undersurface of the LTCC substrate and a solder layer formed on an undersurface of the metal pad layer.

2. The LTCC module according to claim 1, wherein the pad part comprises a Land Grid Array (LGA) type electrode pad.

3. The LTCC module according to claim 1, wherein the solder layer comprises Pb—Sn or Ag—Sn.

4. The LTCC module according to claim 1, wherein the metal pad layer comprises:
a first metal layer formed on an undersurface of the LTCC substrate; and
an Au-plated layer formed on an undersurface of the first metal layer.

5. The LTCC module according to claim 4, wherein the first metal layer comprises Cu or Ag.

6. The LTCC module according to claim 4, wherein the metal pad layer further comprises an Ni-plated layer formed between the first metal layer and the Au-plated layer.

7. The LTCC module according to claim 1, further comprising a surface mounting part formed on a top surface of the LTCC substrate.

8. The LTCC module according to claim 7, wherein the surface mounting part comprises a device encapsulated by a resin encapsulant.

9. A method of manufacturing a Low Temperature Co-fired Ceramic (LTCC) module comprising:
forming a metal pad layer on an undersurface of an LTCC substrate for connection with an external substrate; and
forming a solder layer on an undersurface of the metal pad layer.

10. The method according to claim 9, wherein the step of forming the metal pad layer comprises:
forming a first metal layer on an undersurface of the LTCC substrate; and
forming an Au-plated layer on an undersurface of the first metal layer.

11. The method according to claim 10, wherein the first metal layer is made of metal containing Cu or Ag.

12. The method according to claim 10, wherein the step of forming the metal pad layer further comprises forming an Ni-plated layer on an undersurface of the first metal layer between the step of forming the first metal layer and the step of forming the Au-plated layer.

13. The method according to claim 9, further comprising forming a surface mounting part on a top surface of the LTCC substrate between the step of forming the metal pad layer and the step of forming the solder layer.

14. The method according to claim 9, further comprising dicing a resultant structure with the solder layer formed thereon into individual modules after the step of forming the solder layer.

15. The method according to claim 14, further comprising mounting the diced individual modules on the external substrate after the step of dicing into individual modules.

16. The method according to claim 15, wherein the step of mounting the individual modules on the external substrate comprises:
forming a solder on a mounting surface of the external substrate; and
heating the solder layer of the LTCC module and the solder of the external substrate to bond the solder layer of the LTCC module and the solder of the external substrate together.

17. The method according to claim 16, wherein the solder layer of the LTCC module and the solder of the external substrate are made of the same material.
